(19) United States
(12) Patent Application Publication
(10) Pub. No.: US 2023/0152648 A1
(43) Pub. Date: May 18, 2023

(54) Switchable Transparent Display with Laminated Switching Panel

(71) Applicant: Dell Products L.P., Round Rock, TX (US)

(72) Inventors: Guen Taek Oh, Singapore (SG); Eun Seok Kim, Singapore (SG)

(73) Assignee: Dell Products L.P., Round Rock, TX (US)

(21) Appl. No.: 17/526,577

(22) Filed: Nov. 15, 2021

(51) Int. Cl. G02F 1/137; G02F 1/1335; G02F 1/1343; H01L 27/32

(52) U.S. Cl. CPC G02F 1/137; G02F 1/133531; G02F 1/13439; H01L 27/3232; G02F 2202/28; G02F 2201/44

(57) ABSTRACT

Described herein is a transparent display that provides for transparency and readability modes. A transparent panel is optically bound to a switching panel. The switching panel includes a liquid crystal display (LCD) panel; electrically conductive optical layers connected to either side of the LCD panel; polarizers that filter light through the electrically conductive optical layers and the LCD panel. A switching circuit that provides current to the conductive optical layer to align molecules of the LCD panel for transparency or readability.

### BACKGROUND OF THE INVENTION

### Field of the Invention

The present invention relates to displays implemented by information handling systems. More specifically, embodiments of the invention provide for a transparent display with a switching panel.

### Description of the Related Art

As the value and use of information continues to increase, individuals and businesses seek additional ways to process and store information. One option available to users is information handling systems. Information handling systems include personal computers (PC), server computers, such as desktops. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

Information handling systems implement displays, such as external monitors, to provide visual output to users. A particular type of display is a transparent display. The transparent display allows images to be projected or shown on both sides of the display. There are numerous applications for transparent displays, such for retail, hospitality, automotive, and smart appliance. For example, in retail signage applications, it may be desirable to show physical products or items behind a transparent display, allowing information and other images to be shown on the transparent display. In hospitality applications, a provider may want to share information with a face-to-face customer, where the information is simultaneously shared on the transparent display. Automotive applications can provide for “heads up” type display information. Smart appliance applications can provide the ability “look” into an appliance, such as a refrigerator, and provide information on the display.

There may be instances when a user desires to use a transparent display as a “regular” monitor, and particularly when connected to an information handling system. In order to increase readability, transparent displays may be set to “black pattern” to reduce light transmittance; however, there can still be a 40% transmittance rate, with ambient and pass-through light affecting readability as a regular monitor. The only acceptable condition may be in a completely darken room where no ambient light or pass-through light exists. Therefore, there is a trade off as to transparency and readability for transparent displays.

### SUMMARY OF THE INVENTION

A transparent display comprising: a transparent panel optically bound to a switching panel, wherein the switching panel comprises: a liquid crystal display (LCD) panel; electrically conductive optical layers connected to either side of the LCD panel; polarizers that filter light through the electrically conductive optical layers and the LCD panel; and a switching circuit that provides current to the conductive optical layer to align molecules of the LCD panel for transparency or readability.

A display device comprising: a transparent panel; an optically clear binding layer; and a switching panel that is bond to the transparent panel by the optically clear binding layer, wherein the switching panel comprises: a liquid crystal display (LCD) panel; electrically conductive optical layers connected to either side of the LCD panel; polarizers that filter light through the electrically conductive optical layers and the LCD panel; and a switching circuit that provides current to the conductive optical layer to align molecules of the LCD panel for transparency or readability.

A computer-implementable method for providing transparency and readability in a transparent display with a switching panel comprising: determining if transparency or readability is desired; activating or deactivating the switching panel based on whether transparency or readability, wherein the switching panel comprises: a liquid crystal display (LCD) panel; electrically conductive optical layers connected to either side of the LCD panel; polarizers that filter light through the electrically conductive optical layers and the LCD panel; and a switching circuit that provides current to the conductive optical layer to align molecules of the LCD panel for transparency or readability.

### BRIEF DESCRIPTION OF THE DRAWINGS

The present invention may be better understood, and its numerous objects, features and advantages made apparent to those skilled in the art by referencing the accompanying drawings. The use of the same reference number throughout the several figures designates a like or similar element.

FIG. 1 is a general illustration of components of an information handling system as implemented in the present invention;

FIG. 2 illustrates a system implementing a transparent display with a switching panel;

FIG. 3 illustrates a configuration of transparent display with a switching panel in transparency mode.

FIG. 4 illustrates a configuration of transparent display with a switching panel in readability mode;

FIG. 5 illustrates a switching panel structure; and

FIG. 6 is a generalized flowchart for providing transparency and readability in a transparent display with a switching panel.

### DETAILE D DESCRIPTION

Various implementations provide for a switching panel to be laminated to a transparent display panel surface, such as an OLED display. A clear direct bond between the switching panel and display panel can be provided using an optical clear adhesive (OCA), optical clear resin (OCR) or other binding agent or method. The switching panel is turned “on” when transparency is desired, such as during interactive work instances, public usage/presentation, commercial usage/presentation, etc. The switching panel is turned “off” when high readability is desired, such as during office work, watching a video/movie, conference calls, etc.

For purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, gaming, or other purposes. For example, an information handling system may be a personal computer, a network storage device, or any other suitable device and may vary in size, shape, performance, functionality, and price. The information handling system may include random access memory (RAM), one or more processing resources such as a central processing unit (CPU) or hardware or software control logic, ROM, and/or other types of nonvolatile memory. Additional components of the information handling system may include one or more disk drives, one or more network ports for communicating with external devices as well as various input and output (I/O) devices, such as a microphone, keyboard, a video display, a mouse, etc. The information handling system may also include one or more buses operable to transmit communications between the various hardware components.

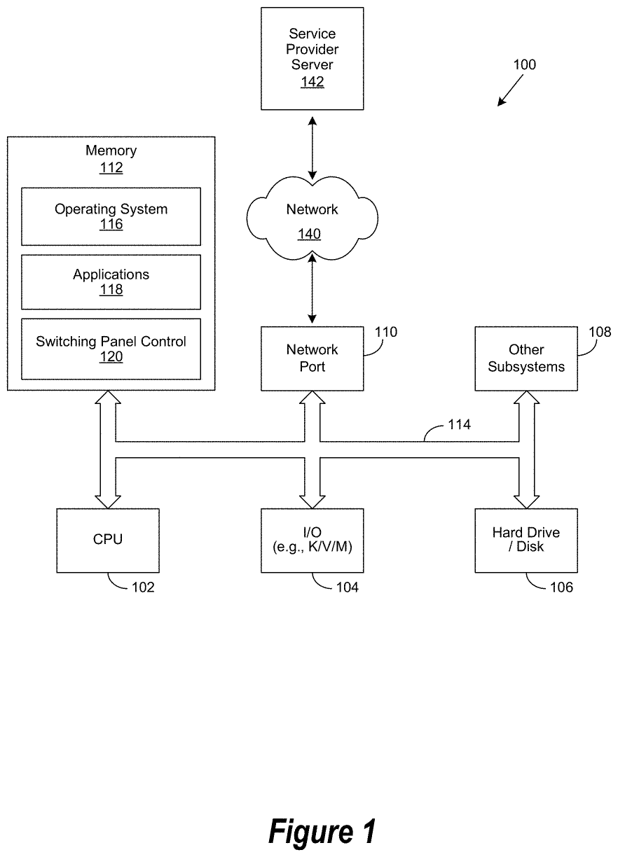

FIG. 1 is a generalized illustration of an information handling system 100 that can be used to implement the system and method of the present invention. The information handing system 100 can be a host to the peripheral devices described herein.

The information handling system 100 includes a processor (e.g., central processor unit or “CPU”) 102, input/output (I/O) devices 104, such as a microphone, a keyboard, a video/display, a mouse, and associated controllers (e.g., K/V/M), a hard drive or disk storage 106, and various other subsystems 108. In various implementations, the video/display of devices 104 is a transparent display, which can be configured in various embodiments, such as monitor, smart window, consumer/retail display, etc.

In various embodiments, the information handling system 100 also includes network port 110 operable to connect to a network 140, where network 140 can include one or more wired and wireless networks, including the Internet. Network 140 is likewise accessible by a service provider server 142. The information handling system 100 likewise includes system memory 112, which is interconnected to the foregoing via one or more buses 114. System memory 112 can be implemented as hardware, firmware, software, or a combination of such. System memory 112 further includes an operating system (OS) 116. Embodiments provide for the system memory 112 to include one or more applications 118. System memory 112 can also include a switching panel control 120 application used to control a connected transparent display as discussed above. Implementations can also provide for a control through I/O connection 104 to switch on or off the connected transparent display.

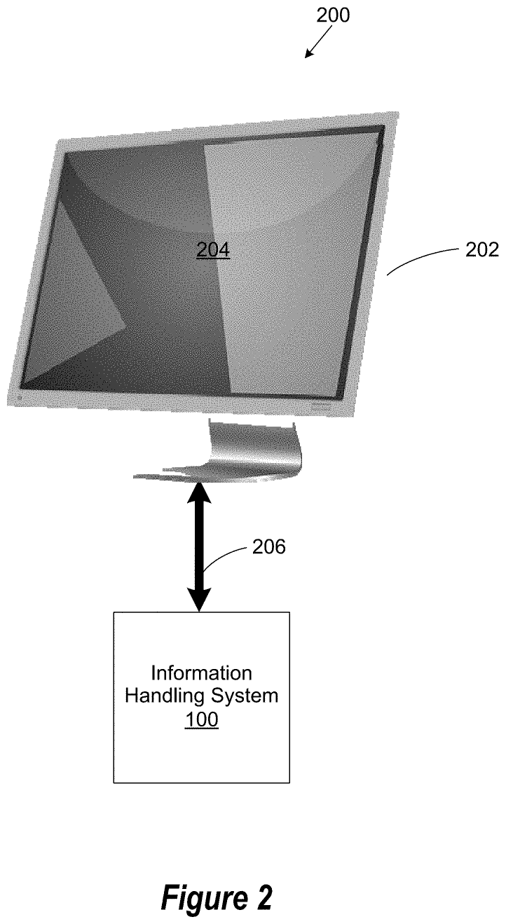

FIG. 2 shows a system implementing a transparent display with a switching panel. As discussed, a transparent display or transparent display device can be embodied as a monitor, smart window, consumer/retail display. In the system 200, a monitor 200 is used as an example. The monitor 202 includes a transparent display 204. In a transparency mode, the display 204 is visible from either side (i.e., front and back) of the monitor 202.

Implementations provide for the monitor 202 and transparent display 204 to be connected to and communicate with an information handling system 100. As discussed in FIG. 1, connection may be provided through one or more busses 114 between I/O devices 104 (e.g., monitor 202) with information handling system 100. A connection/communication 206 is provided between monitor 202 and information handling system 100.

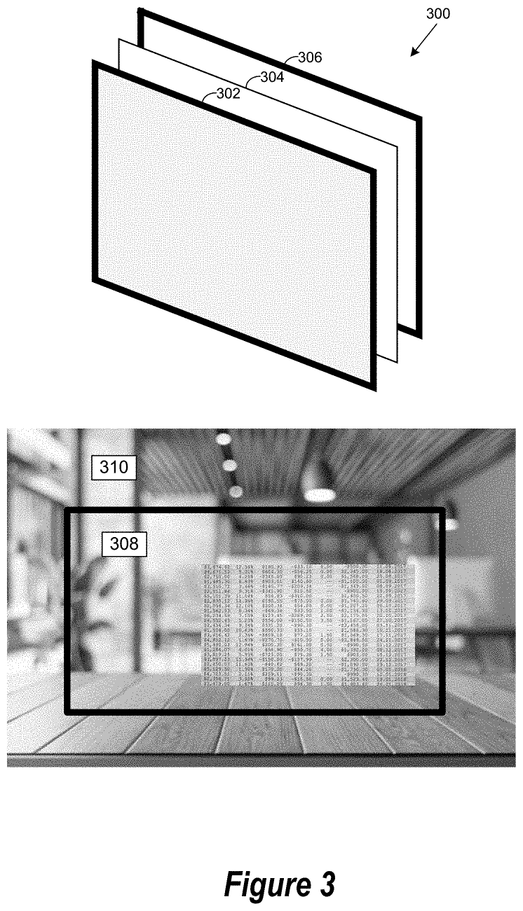

FIG. 3 shows a configuration of transparent display with a switching panel in transparency mode 300. Implementations provide for configuration to include a transparent panel 302. Embodiments provide for the transparent panel 302 to be a transparent organic light emitting diode (OLED) panel. The transparent panel 302 can be implemented as part of the monitor 202 and transparent display 204 described above.

Implementations provide for an optical clear binding layer 304, such as optical clear adhesive (OCA) and optical clear resin (OCR). It is to be understood that other binding agents and methods can be implemented. The optical clear binding layer 304 binds the transparent panel 302 to a switching panel 306. The bond switching panel 306 can be implemented as part of the monitor 202 and transparent display 204 described above.

The switching panel 306, as further described herein, is turned on to provide transparency. As discussed above in FIG. 1, turning on or off the switching panel 306 may be performed through the information handling system 100. In other implementations, the switching panel 306 can be turned on or off directly at the monitor 202.

In transparency mode 300, the switching panel 306 is shown as clear or transparent. The display 308 shows transparency, where a physical background 310 is transparent through the display 308.

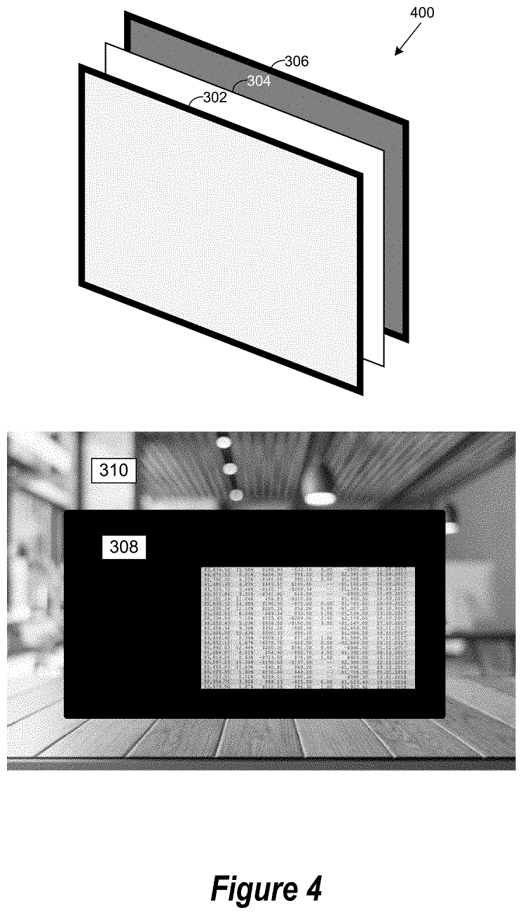

FIG. 4 shows a configuration of transparent display with a switching panel in readability mode 400. The switching panel 306, as further described herein, is turned off to provide readability, where the switching panel 306 is darkened. As discussed above in FIG. 1, turning on or off the switching panel 306 may be performed through the information handling system. In other implementations, the switching panel 306 can be turned on or off directly at the monitor 202.

In readability mode 400, the switching panel 306 is shown as black or darken. The display 308 shows an opaque or darken screen, where only the input to the display is shown. The view of physical background 310 is blocked through the display 308.

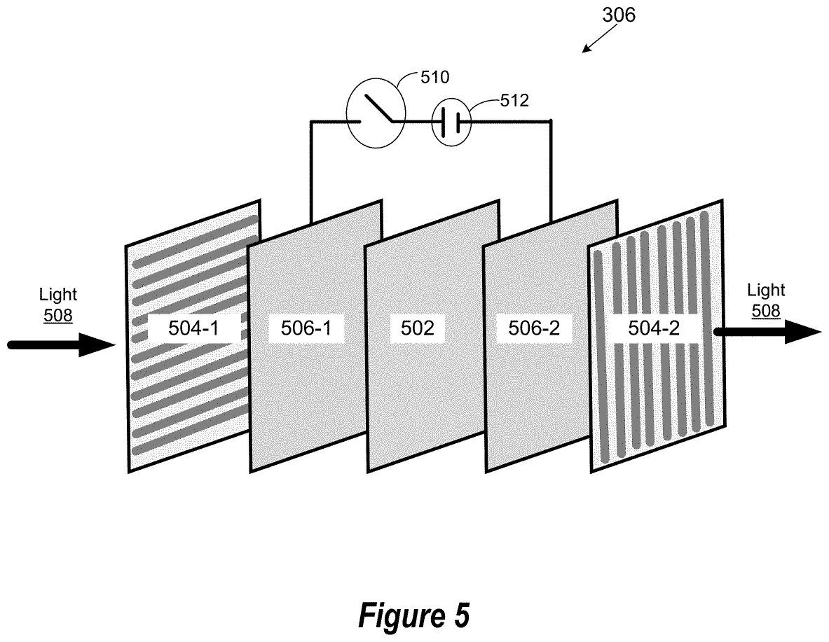

FIG. 5 shows switching panel structure. Embodiments provide for the switching panel 306 to include a liquid crystal display (LCD) layer or panel 502. The LCD 502 can include various types of LCD panels, such as twisted nematic (TN), in plane switching (IPS) (also referred to as plane line switching or PLS), vertical alignment (VA) (also referred to as super vertical alignment or SVA), etc. The types of LCD panels are differentiated by how the alignment of molecules with the LCD when voltage is applied or not applied. As will be further discussed when voltage is applied or not applied to the switching panel 306, molecules of the LCD 502 are aligned to provide transparency or readability.

Embodiments provide for the use of two polarizers 504-1 and 504-2. The polarizers 504-1 and 504-2 act as a filter for light. Implementations provide for one of the polarizers 504 (e.g., polarizer 504-1) to be at “0” degrees and the other polarizers 504 (e.g., polarizer 504-2) to be at “90” degrees alignment to the first polarizer 504 (e.g., polarizer 504-1). The polarizers 504 are arranged, such that without twisting, light cannot pass through the polarizers 504.

Embodiments provide for the switching panel 306 to include indium tin oxide (ITO) layers 506-1 and 506-2. Indium tin oxide (ITO) is a transparent conducting oxide with characteristics of electrical conductivity and optical transparency. Implementations provide for the ITO layers 506-1 and 506-2 to be thin films. The ITO layers 506-1 and 506-2 are placed respectively between the LCD 502 and polarizers 504-1 and 504-2. The ITO layers 506 are conductive and provide voltage to the LCD 502, such that when the switching panel 306 is turned on, molecules of the LCD 502 are aligned to provide transparency. In contrast, when the switching panel 306 is turned off, molecules of the LCD 502 are aligned to provide readability.

Light 508, such as ambient light or light from the transparent panel 302 is filtered by polarizer 504-1. A switch 510 is either turned on or off, providing current to the ITO layers 506-1 and 506-2. Implementations provide for a capacitor 512 to store current to avoid a lag between opening can closing the switch 510.

Implementations provide for the switch 510 and capacitor to be part of an electrical circuit of a monitor, such as monitor 202, or other transparent display. As discussed, turning on or off the switching panel 306 may be performed through the information handling system 100. The turning on or off would be activating or deactivating the switch 510. In other implementations, the switching panel 306 and switch 510, can be turned on or off directly at the monitor 202 or other transparent display.

Current from ITO layers 506-1 and 506-2 aligns the molecules of LCD 502 to provide for transparency (i.e., switch 510 closed), allowing light 508 to pass through polarizer 504-1. When no current flows molecules of the LCD 502 are aligned to provide readability (i.e., switch 510 open), preventing light 508 from passing. Therefore, with the controlling of the shape of the molecules of the LCD 502 through application of electricity on ITO layers 506-1 and 506-2, the path of light 508 can be changed/adjusted for the transparent panel 302.

As discussed, the LCD 502 may be implemented as various types of LCD panels based on the how molecules of the LCD panel are aligned when voltage is applied or not applied. As discussed, the types include TN/, IPS/PLS, VA/SVA, etc. Since the detailed mechanisms and structures are not the same for the different types, consideration or adjustment is performed as to the position of the ITO layers 506-1 and 506-2, the shape of the LCD 502, etc.

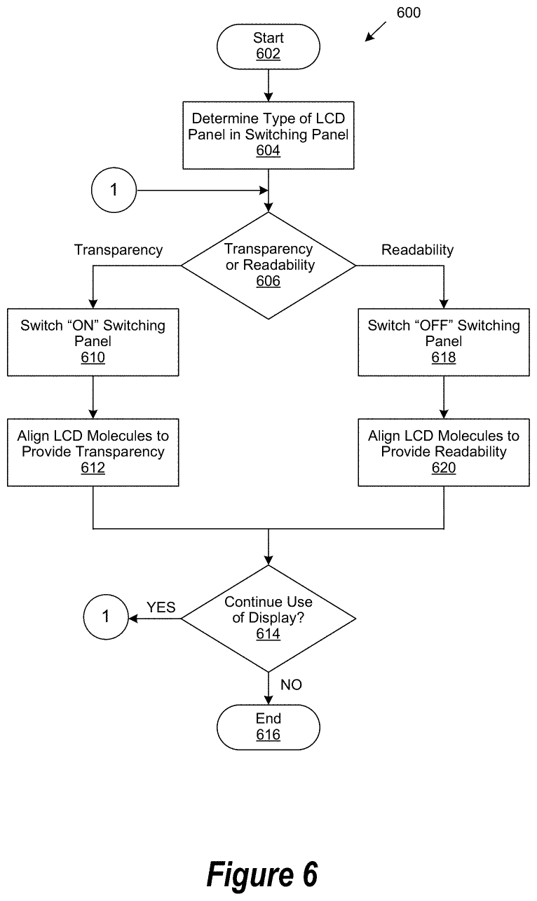

FIG. 6 shows a generalized flowchart for providing transparency and readability in a transparent display with a switching panel. The order in which the method is described is not intended to be construed as a limitation, and any number of the described method steps may be combined in any order to implement the method, or alternate method. Additionally, individual steps may be deleted from the method without departing from the spirit and scope of the subject matter described herein. Furthermore, the method may be implemented in any suitable hardware, software, firmware, or a combination thereof, without departing from the scope of the invention.

At step 602, the process 600 starts. At step 604, a determination is performed as to the type of LCD panel 502 is implemented in the switching panel 306. The types include TN/, IPS/PLS, VA/SVA, etc. and are defined based on the how molecules of the LCD panel 502 are aligned when voltage is applied or not applied.

If transparency mode of the transparent display such as transparent display 204 is desired, then following the “Transparency” branch of step 606, at step 610, the switching panel 306 and particularly the switch 510 is turned on. At step 612, current applied to the LCD panel 502, such through ITO layers 506-1 and 506-2 aligns the molecules of the LCD panel 502 to provide transparency. If continued use of the transparent display 204 is desired, then following the “YES” branch of step 614, the process 600 goes back to step 606. If continued use of the transparent display 204 is not desired, then following the “NO” branch of step 614, at step 616, the process 600 ends.

If readability mode of the transparent display such as transparent display 204 is desired, then following the “Readability” branch of step 606, at step 618, the switching panel 306 and particularly the switch 510 is turned off. At step 620, without current the molecules of the LCD panel 502 are aligned to provide readability. If continued use of the transparent display 204 is desired, then following the “YES” branch of step 614, the process 600 goes back to step 606. If continued use of the transparent display 204 is not desired, then following the “NO” branch of step 614, at step 616, the process 600 ends.

The present invention is well adapted to attain the advantages mentioned as well as others inherent therein. While the present invention has been depicted, described, and is defined by reference to particular embodiments of the invention, such references do not imply a limitation on the invention, and no such limitation is to be inferred. The invention is capable of considerable modification, alteration, and equivalents in form and function, as will occur to those ordinarily skilled in the pertinent arts. The depicted and described embodiments are examples only and are not exhaustive of the scope of the invention.

As will be appreciated by one skilled in the art, the present invention may be embodied as a method, system, or computer program product. Accordingly, embodiments of the invention may be implemented entirely in hardware, entirely in software (including firmware, resident software, micro-code, etc.) or in an embodiment combining software and hardware. These various embodiments may all generally be referred to herein as a “circuit,” “module,” or “system.” Furthermore, the present invention may take the form of a computer program product on a computer-usable storage medium having computer-usable program code embodied in the medium.

Any suitable computer usable or computer readable medium may be utilized. The computer-usable or computer-readable medium may be, for example, but not limited to, an electronic, magnetic, optical, electromagnetic, infrared, or semiconductor system, apparatus, or device. More specific examples (a non-exhaustive list) of the computer-readable medium would include the following: a portable computer diskette, a hard disk, a random-access memory (RAM), a read-only memory (ROM), an erasable programmable read-only memory (EPROM or Flash memory), a portable compact disc read-only memory (CD-ROM), an optical storage device, or a magnetic storage device. In the context of this document, a computer-usable or computer-readable medium may be any medium that can contain, store, communicate, or transport the program for use by or in connection with the instruction execution system, apparatus, or device.

Computer program code for carrying out operations of the present invention may be written in an object-oriented programming language such as Java, Smalltalk, C++ or the like. However, the computer program code for carrying out operations of the present invention may also be written in conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through a local area network (LAN) or a wide area network (WAN), or the connection may be made to an external computer (for example, through the Internet using an Internet Service Provider).

Embodiments of the invention are described with reference to flowchart illustrations and/or step diagrams of methods, apparatus (systems) and computer program products according to embodiments of the invention. It will be understood that each step of the flowchart illustrations and/or step diagrams, and combinations of steps in the flowchart illustrations and/or block diagrams, can be implemented by computer program instructions. These computer program instructions may be provided to a processor of a general-purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram step or steps.

These computer program instructions may also be stored in a computer-readable memory that can direct a computer or other programmable data processing apparatus to function in a particular manner, such that the instructions stored in the computer-readable memory produce an article of manufacture including instruction means which implement the function/act specified in the flowchart and/or block diagram block or blocks.

The computer program instructions may also be loaded onto a computer or other programmable data processing apparatus to cause a series of operational steps to be performed on the computer or other programmable apparatus to produce a computer implemented process such that the instructions which execute on the computer or other programmable apparatus provide steps for implementing the functions/acts specified in the flowchart and/or block diagram block or blocks.

The present invention is well adapted to attain the advantages mentioned as well as others inherent therein. While the present invention has been depicted, described, and is defined by reference to particular embodiments of the invention, such references do not imply a limitation on the invention, and no such limitation is to be inferred. The invention is capable of considerable modification, alteration, and equivalents in form and function, as will occur to those ordinarily skilled in the pertinent arts. The depicted and described embodiments are examples only and are not exhaustive of the scope of the invention.

Consequently, the invention is intended to be limited only by the spirit and scope of the appended claims, giving full cognizance to equivalents in all respects.

1. A transparent display comprising:
a transparent panel optically bound to a switching panel, wherein the switching panel comprises:
a liquid crystal display (LCD) panel;
electrically conductive optical layers connected to either side of the LCD panel;
polarizers that filter light through the electrically conductive optical layers and the LCD panel; and
a switching circuit that provides current to the conductive optical layers to align molecules of the LCD panel for transparency or readability, wherein the molecules of the LCD panel are aligned as twisted nematic (TN), in plane switching (IPS), plane line switching (PLS), vertical alignment (VA), or super vertical alignment or (SVA) and the LCD panel is differentiated based on the alignment of the molecules.

2. The transparent display of claim 1, wherein the transparent display is implemented in a computer monitor, smart window or consumer retail display.

3. The transparent display of claim 1, wherein the transparent panel is an organic light emitting diode (OLED) panel.

4. The transparent display of claim 1, wherein the transparent panel is bound using an optical clear adhesive (OCA) layer or an optical clear resin (OCR) layer.

5. (canceled)

6. The transparent display of claim 1, wherein the electrically conductive optical layers are indium tin oxide.

7. The transparent display of claim 1, wherein the polarizers are aligned 90 degrees from one another.

8. The transparent display of claim 1, wherein turning on or off of the switching panel is from an information handling system or from a display that implements the transparent display.

9. The transparent display of claim 1 wherein turning on the switching panel provides for transparency.

10. A display device comprising:
a transparent panel;
an optically clear binding layer; and
a switching panel that is bond to the transparent panel by the optically clear binding layer, wherein the switching panel comprises:
a liquid crystal display (LCD) panel;
electrically conductive optical layers connected to either side of the LCD panel;
polarizers that filter light through the electrically conductive optical layers and the LCD panel; and
a switching circuit that provides current to the conductive optical layers to align molecules of the LCD panel for transparency or readability, wherein the molecules of the LCD panel are aligned as twisted nematic (TN), in plane switching (IPS), plane line switching (PLS), vertical alignment (VA), or super vertical alignment or (SVA) and the LCD panel is differentiated based on the alignment of the molecules.

11. The display device of claim 10, wherein the display device is one of a computer monitor, smart window or consumer retail display.

12. The display device of claim 10, wherein the transparent panel is an organic light emitting diode (OLED) panel.

13. The display device of claim 10, wherein. the transparent panel is bound using an optical clear adhesive (OCA) layer or an optical clear resin (OCR) layer.

14. (canceled)

15. The display device of claim 10, wherein the electrically conductive optical layers are indium tin oxide.

16. The display device of claim 10, wherein the polarizers are aligned degrees from one another.

17. The display device of claim 10, wherein turning on or off of the switching panel is from an information handling system or from the display device.

18. The display device of claim 10, wherein turning on the switching panel provides for transparency.

19. A computer-implementable method for providing transparency and readability in a transparent display with a switching panel comprising:
determining if transparency or readability is desired;
activating or deactivating the switching panel based on whether transparency or readability, wherein the switching panel comprises:
a liquid crystal display (LCD) panel;
electrically conductive optical layers connected to either side of the LCD panel;
polarizers that filter light through the electrically conductive optical layers and the LCD panel; and
a switching circuit that provides current to the conductive optical layer to align molecules of the LCD panel for transparency or readability, wherein the molecules of the LCD panel are aligned as twisted nematic (TN), in plane switching (IPS), plane line switching (PLS), vertical alignment (VA), or super vertical alignment or (SVA) and the LCD panel is differentiated based on the alignment of the molecules.

20. The computer-implementable method of claim 19, wherein an information handling system controls the switching panel.
